(19) United States
(12) Patent Application Publication
(10) Pub. No.: US 2026/0161190 A1
(43) Pub. Date: Jun. 11, 2026

(54) LOW-DROPOUT REGULATOR DETECTING DROPOUT

(71) Applicant: Samsung Electronics Co., Ltd., Suwon-si (KR)

(72) Inventors: SEKI KIM, Suwon-si (KR); TAKAHIRO NOMIYAMA, Suwon-si (KR)

(21) Appl. No.: 19/404,116

(22) Filed: Dec. 1, 2025

(30) Foreign Application Priority Data
Dec. 9, 2024 (KR) 10-2024-0181824

(51) Int. Cl. G05F 1/575

(52) U.S. Cl. CPC G05F 1/575

(57) ABSTRACT

A low-dropout (LDO) regulator includes a pass transistor having one terminal to which an input voltage is applied and another terminal through which an output voltage is output, and a dropout detection circuit configured to detect dropout. The dropout detection circuit may include a voltage copy circuit configured to generate a copy voltage by copying the output voltage, a first resistor electrically connected between the one terminal of the pass transistor and the voltage copy circuit, a current copy circuit configured to generate a copy current by copying a current flowing through the first resistor, a second resistor electrically connected between a ground terminal and the current copy circuit, and a bypass comparator electrically connected to the current copy circuit and the second resistor.

### CROSS-REFERENCE TO RELATED APPLICATION(S)

This U.S. non-provisional application claims priority under 35 USC § 119 to Korean Patent Application No. 10-2024-0181824, filed on Dec. 9, 2024, in the Korean Intellectual Property Office, the disclosure of which is herein incorporated by reference in its entirety.

### BACKGROUND

Example embodiments relate to a low-dropout (LDO) regulator and, more particularly, to an LDO regulator configured to detect dropout.

An LDO regulator, a type of linear voltage regulator, supplies a constant power supply voltage to an integrated circuit, or the like. The LDO regulator is configured to achieve high power efficiency even when a potential difference between an input voltage and an output voltage is small.

The LDO regulator may use a pass transistor which operates in a saturation region. When dropout occurs, the pass transistor of the LDO regulator shifts to a linear region, reducing loop gain and hindering a normal feedback operation. As a result, an output voltage may significantly drop, causing system malfunctions.

Accordingly, there is a growing demand for LDO regulators configured to detect dropout and stably provide an output voltage.

### SUMMARY

Example embodiments provide an LDO regulator that detects dropout and stably provide an output voltage.

According to an example embodiment, a low-dropout (LDO) regulator includes a pass transistor configured to receive an input voltage through a first terminal and to output an output voltage through a second terminal, and a dropout detection circuit configured to detect dropout, wherein the dropout detection circuit includes a voltage copy circuit configured to generate a copy voltage by copying the output voltage, a first resistor electrically connected between the first terminal of the pass transistor and the voltage copy circuit, a current copy circuit configured to generate a copy current by copying a current flowing through the first resistor, a second resistor electrically connected between a ground terminal and the current copy circuit, and a bypass comparator electrically connected to the current copy circuit and the second resistor.

According to an example embodiment, a low-dropout (LDO) regulator, receiving an input voltage controlled by a voltage regular, includes a pass transistor having one terminal to which an input voltage is applied and another terminal through which an output voltage is output, and a dropout detection circuit configured to detect dropout, wherein, the dropout detection circuit includes a voltage copy circuit configured to generate a copy voltage by copying the output voltage, a first resistor electrically connected between the one terminal of the pass transistor and the voltage copy circuit, a current copy circuit configured to generate a copy current by copying a current flowing through the first resistor, a second resistor electrically connected between a ground terminal and the current copy circuit, and a headroom comparator electrically connected to the current copy circuit and the second resistor.

According to an example embodiment, a dropout detection method of a low-dropout (LDO) regulator includes copying an output voltage using a voltage copy circuit, copying a current flowing through a first resistor, electrically connected between one terminal of a pass transistor and a current copy circuit, using the current copy circuit, comparing a headroom voltage with a headroom reference voltage and generating a headroom comparison signal based on a result of the comparison using a headroom comparator electrically connected to the current copy circuit and a second resistor electrically connected between a ground terminal and the current copy circuit, regulating an input voltage using a voltage regulator in response to the headroom comparison signal, comparing a bypass voltage with a bypass reference voltage and generating a bypass comparison signal based on a result of the comparison using a bypass comparator electrically connected to the second resistor and a third resistor electrically connected between the ground terminal and the second resistor, and regulating a gate node voltage of the pass transistor in response to the bypass comparison signal.

### BRIEF DESCRIPTION OF DRAWINGS

FIG. 1 is a diagram illustrating an LDO regulator.

FIG. 2 is a circuit diagram illustrating a pass transistor and a dropout detection circuit.

FIGS. 3A and 3B are diagrams, each illustrating a voltage drop circuit.

FIG. 4 is a diagram illustrating a voltage boost circuit.

FIG. 5 is a diagram illustrating a bypass comparator.

FIG. 6 is a diagram illustrating the operation of an LDO regulator for generating a bypass comparison signal.

FIG. 7 is a diagram illustrating an LDO regulator according to an example embodiment.

FIG. 8 is a circuit diagram illustrating a dropout detection circuit according to the example embodiment of FIG. 7.

FIG. 9 is a diagram illustrating the operation of an LDO regulator for generating a headroom comparison signal.

FIG. 10 is a diagram illustrating the operation of an LDO regulator for generating a bypass comparison signal and/or a headroom comparison signal.

FIG. 11 is a flowchart illustrating the operation of an LDO regulator.

### DETAILED DESCRIPTION

Hereinafter, example embodiments will be described with reference to the accompanying drawings.

It will be understood that when an element is referred to as being “connected” to another element, it can be directly connected to the other element or intervening elements may be present. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere with a different ordinal number (e.g., “second” in the specification or another claim)

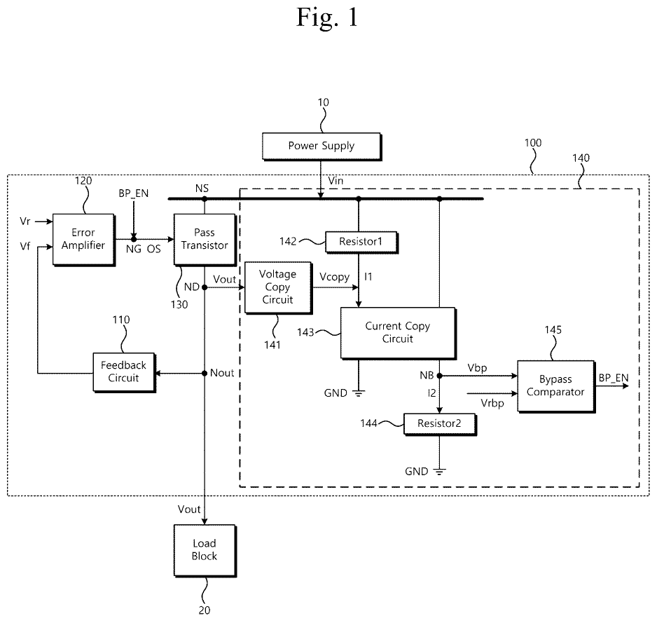

FIG. 1 is a diagram illustrating an LDO regulator 100.

The LDO regulator 100 may receive and use an input voltage Vin from a power supply 10. The LDO regulator 100 may regulate the received input voltage Vin to output an output voltage Vout to an output node Nout. The output voltage Vout may be provided to a load block 20. Hereinafter, the term “dropout voltage” may indicate minimum voltage difference required between input voltage and output voltage for an LDO regulator 100 to maintain a stable output voltage. If the input voltage Vin drops below this threshold (i.e., dropout has occurred, or dropout has been detected), the regulator may no longer provide a consistent output voltage, leading to output voltage instability. For example, if the LDO regulator 100 has a dropout voltage of 200 mV, and the desired output voltage is 5V, then the input voltage needs to be at least 5.2V for the LDO regulator to function correctly.

The LDO regulator 100 may detect and feedback headroom voltage for stably providing the output voltage Vout to the load block 20.

The headroom voltage detected by the LDO regulator 100 may be a difference between the input voltage Vin and the output voltage Vout of the LDO regulator 100. The headroom voltage, which is difference between the input voltage Vin and the output voltage Vout, needs to be greater than the dropout voltage for the LDO regulator 100 to keep the output voltage Vout stable. If the headroom voltage drops below the dropout voltage (i.e., if the input voltage Vin drops to a level at which the voltage difference between the input voltage Vin and the output voltage Vout drops below the dropout voltage), the LDO regulator 100 may not keep the output voltage Vout stable. The state where the headroom voltage drops below the dropout may be called that dropout has occurred or dropout has been detected. For example, in an LDO regulator 100 outputting a voltage of 5 V as the output voltage Vout, when a dropout voltage is 0.2 V and the input voltage Vin is 5.1 V, dropout may have occurred. More specifically, when the headroom voltage (i.e., difference between the input voltage Vin and the output voltage Vout) is 0.1 V which is less than the dropout voltage of 0.2 V, dropout may have occurred. When dropout occurs, the LDO regulator 100 may fail to operate normally, and may not output stable output voltage Vout due to insufficient voltage difference between the input voltage Vin and the output voltage Vout. The LDO regulator 100, according to an example embodiment, may detect dropout by comparing the headroom voltage with a reference voltage, and when dropout is detected, may provide the input voltage to an output node (i.e., output node of the output voltage Vout) to stably provide the output voltage Vout to the load block 20.

Referring to FIG. 1, the LDO regulator 100 may include a feedback circuit 110, an error amplifier 120, a pass transistor 130, and a dropout detection circuit 140.

The feedback circuit 110 may receive the output voltage Vout. The feedback circuit 110 may generate a feedback voltage Vf based on the output voltage Vout. For example, the feedback circuit 110 may include a voltage divider. The feedback circuit 110 may generate the feedback voltage Vf by dividing the output voltage Vout and provide the feedback voltage Vf to the error amplifier 120. The feedback voltage Vf may reflect a state of the output voltage Vout, and the output voltage Vout may be regulated based on the feedback voltage Vf.

The error amplifier 120 may receive a reference voltage Vr, serving as a reference voltage value to regulate the output voltage Vout, and the feedback voltage Vf. The error amplifier 120 may generate an error voltage based on the reference voltage Vr and the feedback voltage Vf. For example, the error amplifier 120 may include an operational amplifier op-amp. The error amplifier 120 may amplify a difference between the reference voltage Vr and the feedback voltage Vf to generate an error voltage. The error amplifier 120 may provide the error voltage to the pass transistor 130.

The pass transistor 130 may be electrically connected to a gate node NG receiving an output of the error amplifier 120 as a driving signal OS, a source node NS receiving the input voltage Vin, and a drain node ND connected to the output node Nout.

The pass transistor 130 may regulate the input voltage Vin to provide the output voltage Vout through the output node Nout. The pass transistor 130 may be electrically connected to the output node Nout, at which the output voltage Vout is output, and the power supply 10. Accordingly, the amount of current provided from the power supply 10 to the output node Nout may vary based on a voltage level of the error voltage received from the error amplifier 120. As a result, the output voltage Vout at the output node Nout may change.

The pass transistor 130 may be connected to the power supply 10 through the source node NS. The output voltage of the power supply 10 may be the input voltage Vin. The pass transistor 130 may receive the input voltage Vin from the power supply 10. For example, the power supply 10 may receive power from a BUCK converter within a power management integrated circuit (PMIC) and generate the input voltage Vin based on the power from the BUCK converter. The BUCK converter is a type of power supply that steps down the input voltage Vin to a lower output voltage. In some embodiments, the power supply 10 may be a battery power supply. As the supply voltage of the battery power supply drops, the voltage level of the input voltage Vin may also decrease.

The pass transistor 130 may receive the input voltage Vin generated by the power supply 10.

The pass transistor 130 may receive the driving signal OS through the gate node NG of the pass transistor 130. The pass transistor 130 may regulate the input voltage Vin to output the output voltage Vout to the output node Nout based on the driving signal OS. For example, the pass transistor 130 may regulate the amount of current provided to the output node Nout based on the driving signal OS.

The driving signal OS provided to the gate node NG of the pass transistor 130 may correspond to an output of the error amplifier 120. For example, a level of the error voltage output from the error amplifier 120 may be provided to the gate node NG of the pass transistor 130 as the driving signal OS. The pass transistor 130 may regulate the amount of current provided to the output node Nout based on the level of the error voltage output from the error amplifier 120.

The dropout detection circuit 140 may receive the output voltage Vout. For example, the dropout detection circuit 140 may be electrically connected to the drain node ND of the pass transistor 130.

The dropout detection circuit 140 may include a voltage copy circuit 141, a first resistor 142, a current copy circuit 143, a second resistor 144, and a bypass comparator 145.

The voltage copy circuit 141 may receive the output voltage Vout from the pass transistor 130. The voltage copy circuit 141 may copy the output voltage Vout to generate a copy voltage Vcopy. For example, the voltage copy circuit 141 may include a unity gain buffer including an operational amplifier Op-Amp. The voltage copy circuit 141 may detect the level of the output voltage Vout, which is an input to the voltage copy circuit 141, and may control the level of the copy voltage Vcopy, which is an output of the voltage copy circuit 141, to be the same with the level of the output voltage Vout through a feedback loop.

One end of the first resistor 142 may be electrically connected to the source node NS of the pass transistor 130, and the other end may be electrically connected to the current copy circuit 143. The input voltage Vin provided to the source node NS is larger than the copy voltage Vcopy, so that a first current I1 may flow through the first resistor 142. According to an example embodiment, the first resistor 142 may be a single resistor, or a plurality of resistors connected in series or parallel.

The current copy circuit 143 may be electrically connected to the first resistor 142 and may receive the first current I1. The current copy circuit 143 may copy the first current I1 to generate a second current I2 and output a second current I2 to a bypass node NB. For example, the current copy circuit 143 may be implemented as a current mirror including at least one transistor. The first current I1 and the second current I2 may be substantially equal. However, this is merely exemplary, and the second current I2 generated by the current copy circuit 143 may be a current copied by amplifying the first current I1 at a specific ratio.

One end of the second resistor 144 may be electrically connected to the current copy circuit 143, and the other end thereof may be electrically connected to a ground terminal GND. Accordingly, the second current I2 may flow through the second resistor 144. A voltage at the bypass node NB may be a bypass voltage Vbp. According to an example embodiment, the second resistor 144 may be a single resistor, or a plurality of resistors connected in series or parallel.

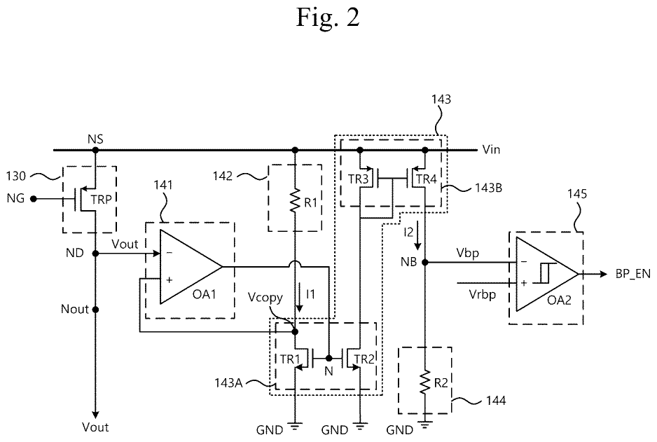

The bypass comparator 145 may receive the bypass voltage Vbp from the bypass node NB. In addition, the bypass comparator 145 may receive a bypass reference voltage Vrbp from an external entity. The bypass comparator 145 may compare the bypass voltage Vbp with the bypass reference voltage Vrbp and generate a bypass comparison signal BP_EN based on a result of the comparison. The bypass comparison signal BP_EN may be provided as an enable signal causing the voltage at the gate node NG of the pass transistor 130 to increase or decrease. The bypass comparison signal BP_EN may be connected to the gate node NG of the pass transistor, and may control the conductivity of the pass transistor 130. For example, the voltage level of the driving signal OS may increase or decrease based on the bypass comparison signal BP_EN. A detailed description of the bypass voltage Vbp will be described later with reference to FIG. 2.

As described above, the LDO regulator 100 according to an example embodiment may detect dropout by generating the bypass comparison signal BP_EN through a comparison between the bypass voltage Vbp and the bypass reference voltage Vrbp. In addition, the LDO regulator 100 may stably output the output voltage Vout by regulating the drive signal OS of the pass transistor 130 based on the voltage level of the error voltage and the bypass comparison signal BP_EN.

FIG. 2 is a circuit diagram illustrating the pass transistor 130 and the dropout detection circuit 140.

Referring to FIG. 2, the pass transistor 130, the voltage copy circuit 141, the first resistor 142, the current copy circuit 143, the second resistor 144, and the bypass comparator 145 may include transistors, operational amplifiers, and/or resistor elements, etc. Detailed descriptions of features identical or similar to those in the example embodiments of FIG. 1 are omitted to avoid redundancy.

The pass transistor 130 may include a transistor TRP. The transistor TRP included in the pass transistor 130 may be a positive-type metal-oxide-semiconductor (PMOS) transistor. Unless otherwise specified in the present specification, an example is provided in which the pass transistor 130 includes a PMOS transistor. However, this is merely exemplary, and in other embodiments, the pass transistor 130 may include a negative-type metal-oxide-semiconductor (NMOS) transistor.

The voltage copy circuit 141 may include an operational amplifier OA1. In the operational amplifier OA1, the output voltage Vout may be applied to an inverting input (−), and a non-inverting input (+) may be connected to an output of the operational amplifier OA1. The output of the operational amplifier OA1 may be fed back to the non-inverting input (+) through a gate node N and a drain node of a transistor TR1, forming a negative feedback loop. Accordingly, the inverting input (−) and the output of the operational amplifier OA1 may be fed back to have the same voltage. As a result, a copy voltage Vcopy output by the operational amplifier OA1 may have the same voltage value as the output voltage Vout.

A typical unity gain buffer has an input signal applied to a non-inverting input (+) and an output signal fed back to an inverting input (−), forming a negative feedback circuit. However, in the case of the voltage copy circuit 141, a signal polarity is inverted once through the gate node N and the drain node of the transistor TR1, so that the polarity of the operational amplifier OA1 should inverted to form a negative feedback loop.

The first resistor 142 may include a resistor element R1. FIG. 2 illustrates an example in which the first resistor 142 includes a single resistor element R1, but this is merely exemplary and the first resistor 142 may include a plurality of resistor elements connected in series or parallel.

The current copy circuit 143 may include at least one current mirror. The operation of a single current mirror 143A will be described with reference to FIG. 2. The current mirror 143A may include a first transistor TR1 and a second transistor TR2. A gate voltage and a drain voltage of the first transistor TR1 may be set to the same value as the copy voltage Vcopy. The gate voltage of the first transistor TR1 (i.e., the voltage of node N) may be an output voltage of the operational amplifier OA1, and the output voltage of the operational amplifier OA1 may be substantially equal to the copy voltage Vcopy (i.e., the drain voltage of the first transistor TR1). Therefore, the gate voltage of the first transistor TR1 is substantially equal to the drain voltage of the first transistor TR1. Because the gate voltage of the first transistor TR1 is substantially equal to the drain voltage of the first transistor TR1, the first transistor TR1 may operate in a saturation region. The first transistor TR1 and the second transistor TR2 may share a common gate node N. In addition, source nodes of the first transistor TR1 and the second transistor TR2 may be connected to a ground terminal GND. Thus, the second transistor TR2 may form the same gate-source voltage as the first transistor TR1. As a result, the same current may flow through the second transistor TR2 as through the first transistor TR1. However, this is merely exemplary, and the copy current I2 generated by the current copy circuit may be an amplified current of the current I1 (i.e., current flowing through the first transistor TR1) at a specific ratio.

The current copy circuit 143 may include two current mirrors, for example, a first current mirror 143A and a second current mirror 143B. Due to inclusion of a plurality of current mirrors in the current copy circuit 143, an effect on the input voltage Vin may be significantly reduced.

When the current copy circuit 143 includes only the first current mirror 143A, the first current mirror 143A may receive the first current I1 based on the value of the input voltage Vin and thus operate based on the input voltage Vin. For example, as the input voltage Vin increases or decreases, the gate-source voltage of the first current mirror 143A may also increase or decrease. The gate-source voltage is directly related to the output current value of the first current mirror 143A, so that the output current value may also increase or decrease. Accordingly, the increase or decrease in the input voltage Vin causes the output current value of the first current mirror 143A to vary sensitively.

However, when both the first current mirror 143A and the second current mirror 143B are used, the second current mirror 143B may operate based on ground GND, unlike the first current mirror 143A. Accordingly, an effect of the increase or decrease in the input voltage Vin on the current copy circuit 143 may be significantly reduced. Unless otherwise specified in the present specification, an example is provided in which the current copy circuit 143 includes two current mirrors.

The second resistor 144 may include a resistor element R2. FIG. 2 illustrates an example in which the second resistor 144 includes a single resistor element R2. However, this is merely exemplary, and the second resistor 144 may include a plurality of resistor elements connected in series or parallel.

The bypass comparator 145 may include an operational amplifier OA2. In the operational amplifier OA2, a bypass voltage Vbp may be applied to an inverting input (−) and a bypass reference voltage Vrbp may be applied to a non-inverting input (+). The operational amplifier OA2 has a significantly high open-loop gain, and thus may amplify even a small difference between the two input voltages Vbp and Vrbp to generate a large output value. The operational amplifier OA2 may output different voltage levels of the bypass comparison signal BP_EN depending on voltage difference between the bypass voltage Vbp and the bypass reference voltage Vrbp. For example, the operational amplifier OA2 may generate and output the bypass comparison signal BP_EN when the bypass voltage Vbp is less than the bypass reference voltage Vrbp.

The bypass voltage Vbp may be determined based on the voltage copy circuit 141, the first resistor 142, the current copy circuit 143, and the second resistor 144.

The bypass voltage Vbp may be a headroom voltage detected by the LDO regulator 100. The headroom voltage may be a voltage difference between the input voltage Vin and the output voltage Vout, and needs to be greater than the dropout voltage. The dropout voltage is a minimum difference between the input voltage and the output voltage required for the LDO regulator to operate normally. In the present application, the headroom voltage may be detected based on the difference between the input voltage Vin and the output voltage Vout. Accordingly, the voltage level of the bypass comparison signal BP_EN may be determined by comparing the bypass voltage Vbp (Vbp=Vin−Vout) with the bypass reference voltage Vrbp which is a predetermined dropout voltage value. The voltage value of the bypass reference voltage Vrbp may be in a range between 50 mV and 500 mV.

The bypass voltage Vbp will be described in detail below.

The first resistor 142 is electrically connected between the source node NS of the pass transistor 130 and the current copy circuit 143, so that a first current I1 may flow therethrough. Considering the resistance R1 of the first resistor 142, the first current I1 may be represented as in Equation 1.

$$I 1 = \frac{Vin - Vcopy}{R 1} \qquad Equation 1$$

The current copy circuit 143 may copy the current I1 flowing through the first resistor 142 to generate a second current I2. The second current I2 may have the same current value as the current I1 flowing through the first resistor 142. When the second current I2 flows through the second resistor 144, the bypass voltage Vbp may be defined at the bypass node NB. The bypass voltage Vbp may be represented as in Equation 2.

$$Vbp = \frac{R2 ( Vin - Vcopy )}{R 1} \qquad Equation 2$$

The first resistor 142 and the second resistor 144 may have the same resistance. For example, R1 and R2 in Equation 2 may be the same. When the first resistor 142 and the second resistor 144 have the same resistance, the bypass voltage Vbp may be represented as in Equation 3 because R1 and R2 are canceled out in the formula of Equation 2.

$$Vbp = Vin - Vcopy \qquad Equation 3$$

The bypass voltage Vbp may be regulated by a ratio of the resistance R1 of the first resistor 142 and the resistance R2 of the second resistor 144. Therefore, the bypass voltage Vbp may not be affected by process variation such as resistance value deviations of the resistors R1 and R2. For example, even when a change in resistance occurs due to a factor such as temperature during operation, the first resistor 142 and the second resistor 144 are disposed in the same LDO regulator 100, so that a variation ratio thereof may remain the same. Accordingly, as long as the variation ratio of the first resistor 142 and the second resistor 144 remains the same, a change in the resistance value during operation may not affect the value of the bypass voltage Vbp.

In another embodiment, the current copy circuit 143 may generate a copy current I2 by amplifying the current I1 flowing through the first resistor 142 at a specific ratio. The bypass voltage Vbp may be represented as in Equation 4.

$$\frac{I 2 * R2 ( Vin - Vcopy )}{I 1 * R 1} \qquad Equation 4$$

Accordingly, the bypass voltage Vbp may be regulated not only by the ratio of the resistance R1 of the first resistor 142 and the resistance R2 of the second resistor 144 but also by the ratio of values of the first current I1 and the copy current I2.

As a result, the bypass voltage Vbp may be a value indicating whether dropout to be detected by the LDO regulator 100 has occurred. For example, the LDO regulator 100 may detect dropout when the bypass voltage Vbp is less than the bypass reference voltage Vrbp, a predetermined dropout voltage.

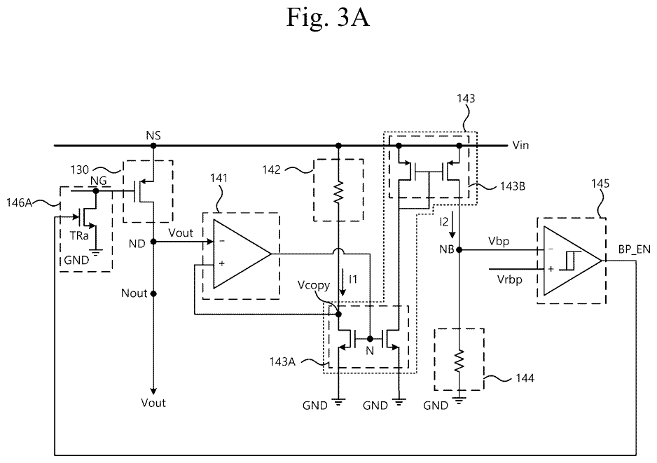

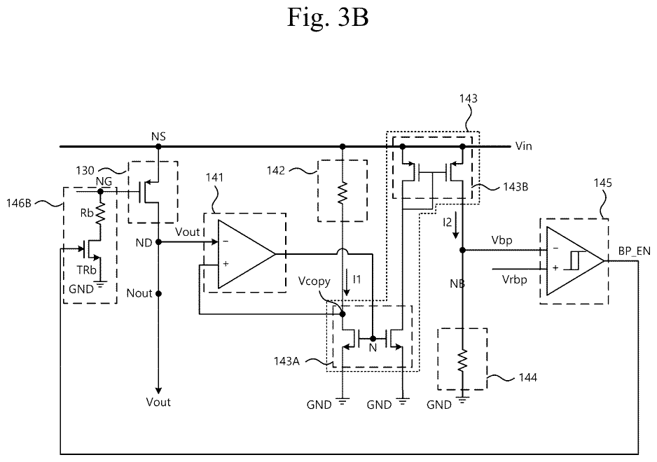

FIG. 3A is a diagram illustrating a voltage drop circuit 146A.

Referring to FIG. 3A, the dropout detection circuit 140 may further include a voltage drop circuit 146A.

The voltage drop circuit 146A may include a transistor TRa. A gate node of the transistor TRa may receive a bypass comparison signal BP_EN generated by the bypass comparator 145. A source node of the transistor TRa may be electrically connected to a ground terminal GND. A drain node of the transistor TRa may be electrically connected to a gate node NG of the pass transistor 130. The transistor TRa may be an NMOS transistor.

The transistor TRa may drop a gate voltage applied to the gate node NG of the pass transistor 130 to a ground voltage in response to the bypass comparison signal BP_EN. For example, when the bypass comparison signal BP_EN is received by the transistor TRa, the transistor TRa may be turned on, allowing current to flow between the drain node NG and the source node of the transistor TRa. An internal resistance component is present in the transistor TRa, so that the transistor TRa may drop the voltage at the drain node NG of the transistor TRa. As a result, the gate voltage applied to the gate node NG of the pass transistor 130 may be dropped by the transistor TRa.

As the gate voltage of the pass transistor 130 drops, the pass transistor 130 may be turned on more fully, and more current may flow through the pass transistor 130. As a result, the input voltage Vin applied to the source node NS and the output voltage Vout at the drain node ND may be substantially equal.

The voltage drop circuit 146a may set the input voltage Vin to be substantially equal to the output voltage Vout in response to the bypass comparison circuit BP_EN to prevent the output voltage Vout from dropping when dropout occurs.

FIG. 3B is a diagram illustrating a voltage drop circuit 146B.

Referring to FIG. 3B, the voltage drop circuit 146B may include a transistor TRb and a resistor Rb. Detailed descriptions of features identical or similar to those in the example embodiments of FIG. 3A are omitted to avoid redundancy.

A gate node of the transistor TRb may receive a bypass comparison signal BP_EN generated by the bypass comparator 145. A source node of the transistor TRb may be electrically connected to a ground terminal GND. A drain node of the transistor TRb may be electrically connected to a resistor Rb. The transistor TRb may be an NMOS transistor.

One end of the resistor Rb may be electrically connected to the gate node NG of the pass transistor 130, and the other end thereof may be electrically connected to the drain node of the transistor TRb. According to example embodiments, the resistor Rb may be a single resistor or a structure in which a plurality of resistors are connected in series or parallel.

By further including the resistor Rb, the voltage drop circuit 146B may prevent a drop in the input voltage Vin caused by a sudden change in the current flowing through the transistor TRb.

For example, when the voltage drop circuit 146B includes only the transistor TRb without the resistor Rb, current may flow between the drain node NG and the source node GND of the transistor TRb, as described above. In general, internal resistance of the transistor TRb is significantly small. Therefore, a gate voltage applied to the gate node NG of the pass transistor 130 may drop rapidly. In response to the abrupt drop in the gate voltage of the pass transistor 130, the current flowing between the source node NS and the drain node ND of the pass transistor 130 may also increase abruptly.

The LDO regulator 100 may receive the input voltage Vin from an input line including a BUCK converter. The input line including the BUCK converter may have inductance. A voltage across the inductance of an input line may be proportional to a rate of change of current. Accordingly, when the current flowing through the pass transistor 130 increases rapidly, a voltage drop may occur across the inductance. As a result, the input voltage Vin may experience a sudden momentary drop, which may disrupt the normal operation of the LDO regulator.

The rapid change in the current flowing through the pass transistor 130 should be prevented to address the above-described issue of the rapid drop in the input voltage Vin. Therefore, the internal resistance of the transistor TRb in the voltage drop circuit 146B may increase. However, this may result in more frequent switching operations of the transistor TRb, thereby increasing power loss. Accordingly, an additional external resistor Rb may be provided to prevent rapid changes in the current flowing through the pass transistor 130 without increasing the internal resistance of the transistor TRb.

The voltage drop circuit 146B may set the output voltage Vout to be substantially equal to the input voltage Vin in response the bypass comparison signal BP_EN to prevent the output voltage from dropping when dropout occurs. In addition, the current flowing through the pass transistor 130 may be prevented from changing rapidly, allowing the LDO regulator 100 to operate stably.

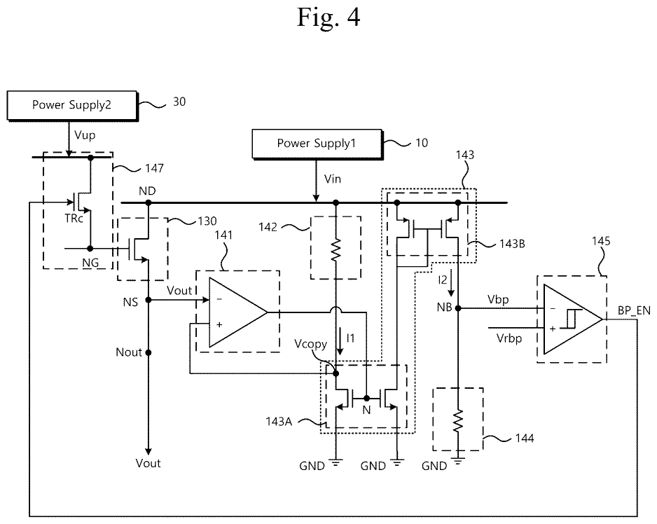

FIG. 4 is a diagram illustrating a voltage boost circuit 147.

Referring to FIG. 4, the pass transistor 200 of the LDO regulator 100 may be an NMOS transistor. The LDO regulator 100 may receive and use a first input voltage Vin from a first power supply 10.

The voltage boost circuit 172 may include a transistor TRc. The transistor TRc may be an NMOS transistor.

A bypass comparison signal BP_EN generated by the bypass comparator 145 may be applied to a gate node of the transistor TRc. A source node of the transistor TRc may be electrically connected to a gate node NG of the pass transistor 130. A second input voltage Vup may be applied to a drain node of the transistor TRc.

The second power supply 30 may provide a second input voltage Vup to the transistor TRc. The second input voltage Vup may have a voltage value, greater than or equal to the first input voltage Vin. The second power supply 30 may receive power from a BUCK converter within a PMIC.

The voltage boost circuit 147 may increase a gate voltage, applied to the gate node NG of the pass transistor 130, to a value of the second input voltage Vup through the transistor TRc in response to a bypass comparison signal BP_EN. For example, when the bypass comparison signal BP_EN is received by the transistor TRc, the transistor TRc be turned on, allowing current to flow between the drain node and the source node NG of the transistor TRc. An internal resistance component is present in the transistor TRc, so that the transistor TRc may increase a voltage at the source node NG of the transistor TRc to a value of the second input voltage Vup. As a result, the gate voltage applied to the gate node NG of the pass transistor 130 may be increased by the transistor TRc.

As the gate voltage of the pass transistor 130 increases, the pass transistor 130 may be turned on more fully. Accordingly, more current may flow through the pass transistor 130. As a result, the first input voltage Vin applied to the drain node ND and the output voltage Vout at the source node NS may be substantially equal.

The voltage boost circuit 147 may set the output voltage Vout to be substantially equal to the first input voltage Vin in response to the bypass comparison signal BP_EN to prevent the output voltage Vout from dropping when dropout occurs.

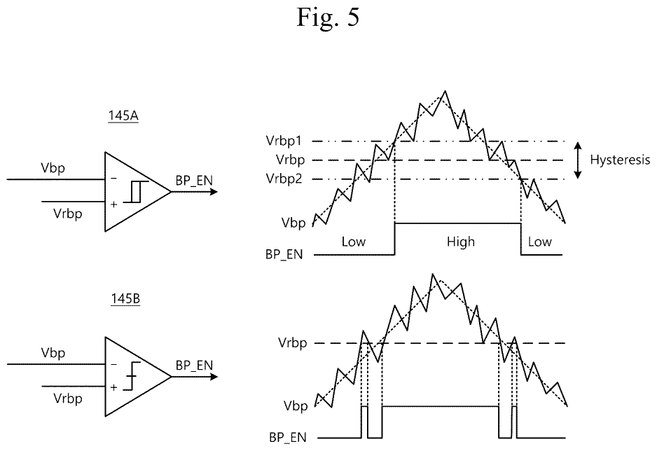

FIG. 5 is a diagram illustrating the bypass comparator 145. Detailed descriptions of features identical or similar to those in the example embodiments of FIGS. 1 and 2 are omitted to avoid redundancy.

The bypass comparator 145 may include a comparator with hysteresis 145A.

The comparator with hysteresis 145A may not immediately change the bypass comparison signal BP_EN to high or low when the bypass voltage Vbp is greater than or less than the bypass reference voltage Vrbp. Instead, the comparator with hysteresis 145A may change the bypass comparison signal BP_EN to high or low when the bypass voltage Vbp exceeds or drops below a specific range with respect to the bypass reference voltage Vrbp. For example, the bypass comparison signal BP_EN may change to high when the bypass voltage Vbp is greater than a reference value Vrbp1 which is greater than the bypass reference voltage Vrbp. In addition, the bypass comparison signal BP_EN may change to low when the bypass voltage Vbp drops below a reference value Vrbp2 which is less than the bypass reference voltage Vrbp.

As a result, the comparator with hysteresis 145A may change the bypass comparison signal BP_EN to high or low when the bypass voltage Vbp exceeds or drops below a specific range, and the bypass comparison signal BP_EN may be less affected from noise included in the bypass voltage Vbp or from unstable state of the bypass voltage Vbp. Thus, the stable operation of the LDO regulator 100 may be achieved.

Referring to FIG. 5, graphs illustrate a first case in which a comparator with hysteresis 145A receives an unstable bypass voltage Vbp and a second case in which a comparator without hysteresis 145B receives an unstable bypass voltage Vbp.

The comparator with hysteresis 145A may change the bypass comparison signal BP_EN to high when the bypass voltage exceeds a reference value Vrbp1 which is greater than the bypass reference voltage Vrbp, and change the bypass comparison signal BP_EN to low when the bypass voltage drops below a reference value Vrbp2 which is less than the bypass reference voltage Vrbp. Accordingly, in spite of an unstable input of the bypass voltage Vbp, the comparator with hysteresis 145A may stably generate the bypass comparison signal BP_EN.

The comparator without hysteresis 145B may change the bypass comparison signal BP_EN to high or low each time the bypass voltage exceeds or drop below the bypass reference voltage Vrbp due to the unstable bypass voltage Vbp. Accordingly, the comparator without hysteresis 145B may inevitably generates an unstable bypass comparison signal BP_EN in response to the unstable bypass voltage Vbp.

Due to the inclusion of the comparator with hysteresis 145A in the bypass comparator 145, the bypass comparator 145 may stably generate the bypass comparison signal BP_EN even when the bypass voltage Vbp is unstably input. However, this is on an example, and in example embodiments, the bypass comparator 145 may include a comparator without hysteresis 145B.

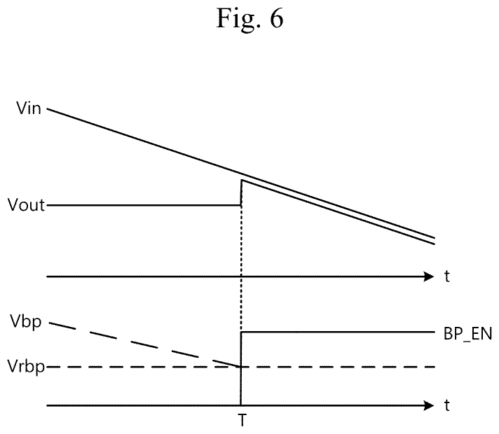

FIG. 6 is a diagram illustrating the operation of the LDO regulator 100 for generating the bypass comparison signal BP_EN. Detailed descriptions of features identical or similar to those in the example embodiments of FIGS. 1 to 5 are omitted to avoid redundancy.

Referring to FIG. 6, dropout detection and supply of stable output voltage Vout by the LDO regulator 100 will be described using an example in which an input voltage Vin decreases continuously.

When the input voltage Vin decreases continuously, the bypass voltage Vbp based on the input voltage Vin may also decrease in response to a decrease in the input voltage Vin. When the bypass voltage Vbp decreases and then drops below the bypass reference voltage Vrbp at time T, the bypass comparison signal BP_EN may be generated accordingly. For example, dropout may be detected at time T.

At time T, in response to the generation of the bypass comparison signal BP_EN due to dropout detection, the pass transistor 130 may be turned on to set the output voltage Vout of the LDO regulator 100 to be substantially equal to the input voltage Vin. Accordingly, even when the decrease in the input voltage Vin causes the occurrence of dropout, the output voltage Vout may be stably output and supplied.

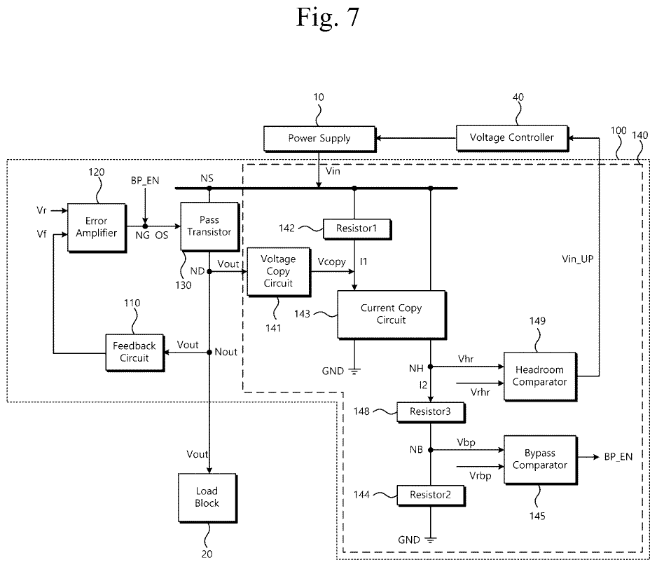

FIG. 7 is a diagram illustrating an LDO regulator 100 according to an example embodiment. Detailed descriptions of features identical or similar to those in the example embodiments of FIG. 1 are omitted to avoid redundancy.

Referring to FIG. 7, the dropout detection circuit 140 may further include a third resistor 148 and a headroom comparator 149.

One end of the third resistor 148 may be electrically connected to the current copy circuit 143, and the other end thereof may be electrically connected to the second resistor 144. Accordingly, the second current I2 may flow through the third resistor 148. A voltage at a headroom node NH may be a headroom voltage Vhr. According to Equation 2, when the sum of the second resistance value or the second resistor R2 and the third resistance value of the third resistor R3 is adjusted to be equal to the first resistance value of the first resistor R1, the headroom voltage Vhr corresponds to voltage difference between the input voltage Vin and the output voltage Vout. According to an example embodiment, the third resistor 148 may be a single resistor or a plurality of resistors connected in series or parallel.

The headroom comparator 149 may receive the headroom voltage Vhr from the headroom node NH. In addition, the headroom comparator 149 may receive a headroom reference voltage Vrhr from an external entity. The headroom reference voltage Vrhr may be higher than the bypass reference voltage Vrbp. The headroom comparator 149 may compare the headroom voltage Vhr with the headroom reference voltage Vrhr to generate a headroom comparison signal Vin_UP based on a result the comparison.

The headroom comparison signal Vin_UP generated by the headroom comparator may control a voltage controller 40. The voltage controller 40 may regulate an input voltage Vin, provided by the power supply 10, to increase or decrease a voltage value. The headroom comparison signal Vin_UP may be provided as an enable signal that controls the voltage controller 40 to increase the voltage of the input voltage Vin provided by the first power supply 10.

As described above, the LDO regulator 100 according to an example embodiment may detect dropout by detecting the headroom voltage Vhr and generating the headroom comparison signal Vin_UP through comparison with the headroom reference voltage Vrhr. In addition, the LDO regulator 100 may control the voltage controller 40 to increase the input voltage Vin in response to the headroom comparison signal Vin_UP, thereby stably outputting the output voltage Vout.

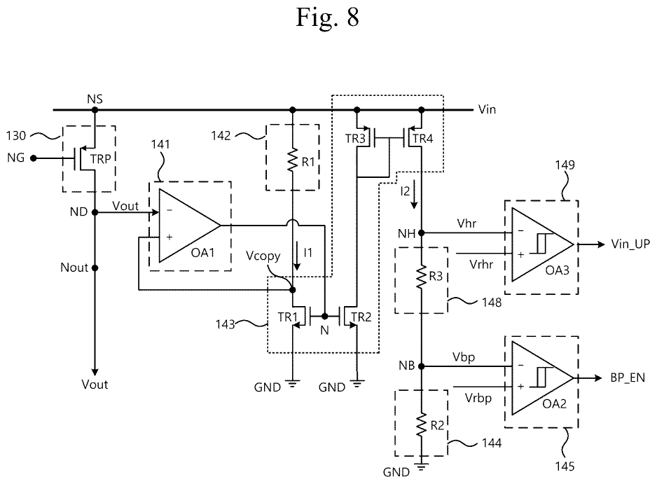

FIG. 8 is a circuit diagram illustrating the dropout detection circuit 140 according to the embodiment of FIG. 7.

Referring to FIG. 8, the third resistor 148 and the headroom comparator 149 may include an operational amplifier and/or resistor elements. Detailed descriptions of features identical or similar to those in the example embodiments of FIG. 2 are omitted to avoid redundancy.

The third resistor 148 may include a resistor element R3. FIG. 8 illustrates an example in which the third resistor 148 includes a single resistor element R3. However, this is merely exemplary, and the third resistor 148 may include a plurality of resistor elements connected in series or parallel.

The headroom comparator 149 may include an operational amplifier OA3. In the operational amplifier OA3, a headroom voltage Vhr may be applied to an inverting input (−) and a headroom reference voltage Vrhr may be applied to a non-inverting input (+). The operational amplifier OA3 has a significantly high open-loop gain, and thus may amplify even a small difference between the two input voltages Vhr and Vrhr to generate a large output value. The operational amplifier OA3 may generate and output a headroom comparison signal Vin_UP when the headroom voltage Vhr is less than the headroom reference voltage Vrhr.

As a result, the headroom voltage Vhr may have a value indicating whether a dropout detected by the LDO regulator 100 has occurred. For example, the LDO regulator 100 may detect dropout when the headroom voltage Vhr is less than the headroom reference voltage Vrhr, a predetermined dropout voltage.

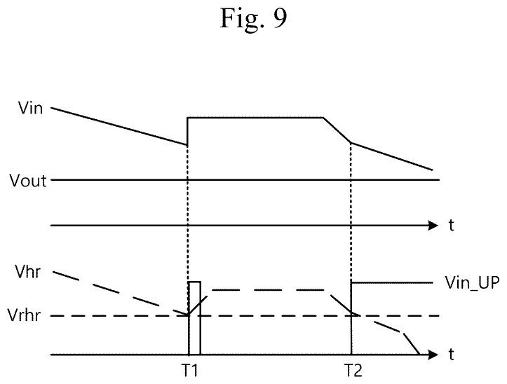

FIG. 9 is a diagram illustrating how the LDO regulator 100 detects dropout in response to the headroom comparison signal Vin_UP and supplies the output voltage Vout. Descriptions of embodiments that overlap or are similar to those explained with reference to FIGS. 1 to 8 will be omitted for brevity.

When the input voltage Vin decreases continuously, the headroom voltage Vhr may also decrease in response to a decrease in the input voltage Vin. When the bypass voltage Vbp decreases and drops below the headroom reference voltage Vrhr, a corresponding headroom comparison signal Vin_UP may be generated. For example, dropout may be detected at times T1 and T2.

At times T1 and T2, the voltage controller 40 may control the first power supply 10 to increase a value of the input voltage Vin in response to the generation of the headroom comparison signal Vin_UP based on dropout detection. For example, when a decrease in the input voltage Vin causes the occurrence of a dropout, the voltage controller 40 may increase the input voltage Vin and generate stable output voltage Vout.

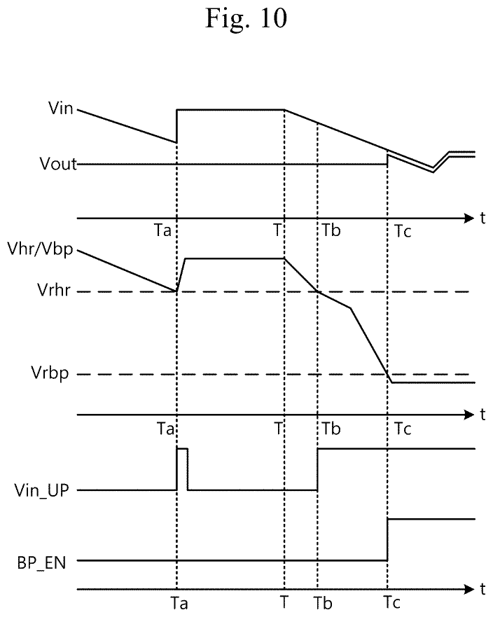

FIG. 10 is a diagram illustrating how the LDO regulator 100 detects dropout and supplies the output voltage Vout in response to the bypass comparison signal BP_EN and/or the headroom comparison signal Vin_UP. Detailed descriptions of features identical or similar to those in the example embodiments of FIGS. 1 to 9 are omitted to avoid redundancy.

Dropout detection and supply of an output voltage Vout by the LDO regulator 100 before time T will be described with reference to FIG. 10. When the input voltage Vin decreases, the headroom voltage Vhr and/or the bypass voltage Vbp, which are values based on the voltage level of the input voltage Vin, may also decrease accordingly. At time Ta, when the headroom voltage Vhr becomes less than the headroom reference voltage Vrhr, the headroom comparator may generate the headroom comparison signal Vin_UP. The voltage controller 40 may control the power supply 10 to increase the value of the input voltage Vin in response to the headroom comparison signal Vin_UP. For example, the LDO regulator 100 may detect dropout and stably supply an output voltage by increasing the input voltage Vin in response to the headroom comparison signal Vin_UP.

Dropout detection and supply of an output voltage Vout supply by the LDO regulator 100 after time T will be described with reference to FIG. 10. When an input voltage Vin decreases, causing the headroom voltage Vhr at time point Tb to drop below the headroom reference voltage Vrhr, the headroom comparison signal Vin_UP may be generated accordingly. In spite of an increase in the input voltage Vin of the voltage controller 40 in response to the generation of the headroom comparison signal Vin_UP, the input voltage Vin may decrease continuously due to issues such as excessive load current generation, causing the bypass voltage Vbp to become lower than the bypass reference voltage Vrbp at time Tc. The bypass comparator may generate the bypass comparison signal BP_EN. The voltage drop circuits 146A and 146B or the voltage boost circuit 147 may regulate a gate voltage of the pass transistor 130 to increase an output voltage Vout to a value of the input voltage Vin in response to the bypass comparison signal BP_EN. For example, the LDO regulator 100 may detect dropout and stably supply the output voltage.

Accordingly, the LDO regulator 100 may increase the value of the input voltage Vin in response to the headroom comparison signal Vin_UP based on a comparison with the headroom reference voltage Vrhr. Then, the LDO regulator 100 may set the value of the output voltage Vout value to be substantially equal to the input voltage Vin value in response to the bypass comparison signal BP_EN based on a comparison with the bypass reference voltage Vrbp. As a result, the LDO regulator 100 may detect dropout and stably supply the output voltage.

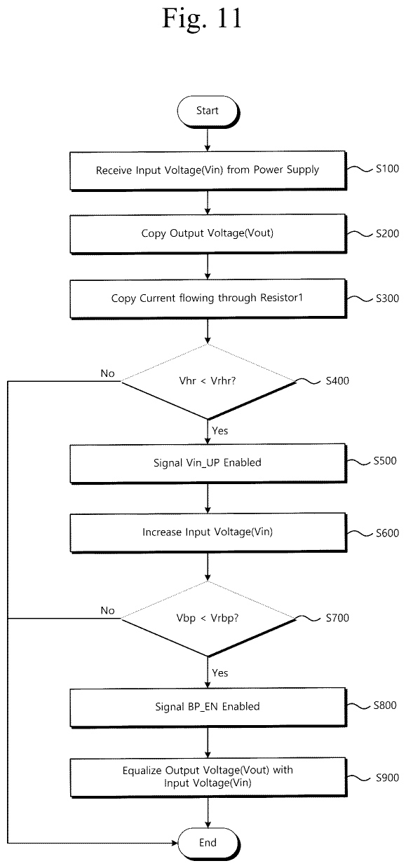

FIG. 11 is a flowchart illustrating the operation of the LDO regulator 100. Detailed descriptions of features identical or similar to those described above are omitted to avoid redundancy.

In operation S100, the LDO regulator 100 may receive the input voltage Vin from the power supply 10.

In S200, the LDO regulator 100 may generate a copy voltage by copying the output voltage Vout, which is voltage level at the output node, using the voltage copy circuit 141.

In operation S300, the LDO regulator 100 may generate a copy current by copying a current, flowing through the first resistor 142, using the current copy circuit based on the copy voltage copied by the voltage copy circuit 141 and the input voltage.

In operation S400, the LDO regulator 100 may compare the headroom voltage Vhr with the headroom reference voltage Vrhr using the headroom comparator 149. The headroom voltage Vhr may be generated based on the copy voltage and the copy current. When the headroom voltage Vhr is greater than or equal to the headroom reference voltage Vrhr, a dropout voltage required for stable operation of the LDO regulator 100 is secured. Therefore, the output voltage Vout may function properly as a power supply.

In operation S500, when the headroom voltage Vhr is less than the headroom reference voltage Vrhr based on a result of the comparison, the LDO regulator 100 may generate the headroom comparison signal Vin_UP.

In operation S600, the LDO regulator 100 may receive an increased input voltage Vin from the power supply 10 based on the control of the voltage controller 40 in response to the headroom comparison signal Vin_UP.

In operation S700, the LDO regulator 100 may compare the bypass voltage Vbp with the bypass reference voltage Vrbp using the bypass comparator 145. The bypass voltage Vbp may be generated based on the copy voltage and the copy current. When the bypass voltage Vbp is greater than or equal to the bypass reference voltage Vrbp, a dropout voltage required for stable operation of the LDO regulator 100 is secured, so the output voltage Vout may function properly as a power supply.

In operation S800, when the bypass voltage Vbp is less than the bypass reference voltage Vrbp based on a result of the comparison, the LDO regulator 100 may generate the first comparison signal BP_EN.

In operation S900, the LDO regulator 100 may regulate the gate node voltage of the pass transistor 130 to set the output voltage Vout to be substantially equal to the input voltage Vin in response to the bypass comparison signal BP_EN.

As set forth above, according to example embodiments, an LDO regulator may detect dropout and stably provide an output voltage.

While example embodiments have been shown and described above, it will be apparent to those skilled in the art that modifications and variations could be made without departing from the scope of the present inventive concept as defined by the appended claims.

What is claimed is:

1. A low-dropout (LDO) regulator comprising:
a pass transistor configured to receive an input voltage through a first terminal and to output an output voltage through a second terminal; and
a dropout detection circuit configured to detect dropout,
wherein the dropout detection circuit comprises:
a voltage copy circuit configured to generate a copy voltage by copying the output voltage;
a first resistor electrically connected between the first terminal of the pass transistor and the voltage copy circuit;
a current copy circuit configured to generate a copy current by copying a current flowing through the first resistor;
a second resistor electrically connected between a ground terminal and the current copy circuit; and
a bypass comparator electrically connected to the current copy circuit and the second resistor.

2. The LDO regulator of claim 1, wherein the first resistor and the second resistor have the same resistance value.

3. The LDO regulator of claim 1, wherein the bypass comparator is configured to compare a bypass voltage with a bypass reference voltage and generate a bypass comparison signal based on a result of the comparison.

4. The LDO regulator of claim 3, wherein the pass transistor is a PMOS transistor, and the LDO regulator further comprises a voltage drop circuit configured to drop a gate node voltage of the pass transistor to a ground voltage in response to the bypass comparison signal.

5. The LDO regulator of claim 4, wherein the voltage drop circuit comprises a transistor electrically connected between the gate node of the pass transistor and a ground terminal.

6. The LDO regulator of claim 5, wherein the voltage drop circuit further comprises at least one resistor having one terminal electrically connected to a drain node of the transistor, and another terminal electrically connected to the gate node of the pass transistor.

7. The LDO regulator of claim 3, wherein the pass transistor is an NMOS transistor, and the LDO regulator further comprises a voltage boost circuit configured to increase a gate node voltage of the pass transistor to a boost voltage in response to the bypass comparison signal.

8. The LDO regulator of claim 7, wherein the boosted voltage is greater than or equal to the input voltage.

9. The LDO regulator of claim 7, wherein the voltage boost circuit comprises:
an NMOS transistor having one terminal electrically connected to the gate node of the pass transistor, and another terminal applied with the boosted voltage; and
a resistor having a first terminal electrically connected to a source node of the NMOS transistor and a second terminal electrically connected to the gate node of the pass transistor.

10. The LDO regulator of claim 3, wherein voltage value of the bypass reference voltage is in a range between 50 mV and 500 mV.

11. The LDO regulator of claim 1, wherein the bypass comparator comprises a hysteresis comparator.

12. The LDO regulator of claim 1, wherein the voltage copy circuit comprises an operational amplifier, and the current copy circuit comprises at least one current mirror comprising a plurality of transistors.

13. The LDO regulator of claim 1, wherein the copy current is an amplified current of the current flowing through the first resistor at a specific ratio.

14. The LDO regulator of claim 1, wherein the input voltage is controlled by a voltage regulator, and the dropout detection circuit further comprises:
a third resistor electrically connected between the second resistor and the current copy circuit; and
a headroom comparator electrically connected to the current copy circuit and the third resistor.

15. The LDO regulator of claim 14, wherein the headroom comparator is configured to compare a headroom voltage with a headroom reference voltage and generate a headroom comparison signal based on a result of the comparison.

16. The LDO regulator of claim 15, wherein the voltage regulator is configured to increase the input voltage in response to the headroom comparison signal.

17. The LDO regulator of claim 14, wherein the headroom comparator comprises a hysteresis comparator.

18. A low-dropout (LDO) regulator receiving an input voltage controlled by a voltage regulator, the LDO regulator comprising:
a pass transistor having one terminal to which an input voltage is applied and another terminal through which an output voltage is output; and
a dropout detection circuit configured to detect dropout,
wherein:
the dropout detection circuit comprises:
a voltage copy circuit configured to generate a copy voltage by copying the output voltage;
a first resistor electrically connected between the one terminal of the pass transistor and the voltage copy circuit;
a current copy circuit configured to generate a copy current by copying a current flowing through the first resistor;
a second resistor electrically connected between a ground terminal and the current copy circuit; and
a headroom comparator electrically connected to the current copy circuit and the second resistor.

19. The LDO regulator of claim 18, wherein the headroom comparator is configured to compare a headroom voltage with a headroom reference voltage and generate a headroom comparison signal based on a result of the comparison, and
the voltage regulator is configured to increase the input voltage in response to the headroom comparison signal.

20. A dropout detection method of a low-dropout (LDO) regulator, the dropout detection method comprising:
copying an output voltage using a voltage copy circuit;
copying a current flowing through a first resistor, electrically connected between one terminal of a pass transistor and a current copy circuit, using the current copy circuit;
comparing a headroom voltage with a headroom reference voltage and generating a headroom comparison signal based on a result of the comparison using a headroom comparator electrically connected to the current copy circuit and a second resistor electrically connected between a ground terminal and the current copy circuit;
regulating an input voltage using a voltage regulator in response to the headroom comparison signal;
comparing a bypass voltage with a bypass reference voltage and generating a bypass comparison signal based on a result of the comparison using a bypass comparator electrically connected to the second resistor and a third resistor electrically connected between the ground terminal and the second resistor; and
regulating a gate node voltage of the pass transistor in response to the bypass comparison signal.
